(19) United States
(12) Patent Application Publication
(10) Pub. No.: US 2024/0135048 A1
(43) Pub. Date: Apr. 25, 2024

(54) ADDITIVELY MANUFACTURED, THERMALLY OPTIMIZED ROCKET MOTOR NOZZLE DESIGN

(71) Applicants: Garrett McDaniel, Colorado Springs, CO (US); Karl Kulling, Colorado Springs, CO (US); Christopher N. Yakacki, Denver, CO (US); Kannan Premanth, Lone Tree, CO (US); William Schupbach, Denver, CO (US)

(72) Inventors: Garrett McDaniel, Colorado Springs, CO (US); Karl Kulling, Colorado Springs, CO (US); Christopher N. Yakacki, Denver, CO (US); Kannan Premanth, Lone Tree, CO (US); William Schupbach, Denver, CO (US)

(21) Appl. No.: 18/462,274

(22) Filed: Sep. 6, 2023

Related U.S. Application Data
(60) Provisional application No. 63/415,837, filed on Oct. 13, 2022.

(51) Int. Cl. G06F 30/15; B64F 5/10; F02K 9/97

(52) U.S. Cl. CPC G06F 30/15; B64F 5/10; F02K 9/97; B33Y 10/00

(57) ABSTRACT

A computer system, for manufacturing a solid rocket motor nozzle using additive manufacturing, inputs into a temperature field algorithm at least one design parameter for the solid rocket motor nozzle. The temperature field algorithm generates a first temperature field for an initial solid rocket motor nozzle design. The first temperature field is provided to a nozzle-geometry optimization algorithm. The nozzle-geometry optimization algorithm generates a first updated solid rocket motor nozzle design. The temperature field algorithm then generates a second temperature field for the first updated solid rocket motor nozzle design. The second temperature field is provided to the nozzle-geometry optimization algorithm. The nozzle-geometry optimization algorithm generates a second updated solid rocket motor nozzle design. When the second updated solid rocket motor nozzle design meets a specified project requirement, the computer system generates a file for additively manufacturing the second updated solid rocket motor nozzle design.

### CROSS-REFERENCE TO RELATED APPLICATIONS

This application claims the benefit of and priority to U.S. Provisional Patent Application Ser. No. 63/415,837 filed on 13 Oct. 2022 and entitled “ADDITIVELY MANUFACTURED, THERMALLY OPTIMIZED ROCKET MOTOR NOZZLE DESIGN,” which application is expressly incorporated herein by reference in its entirety.

### BACKGROUND

The fields of rocket science and rocket engineering have become increasingly important portions of the aerospace and defense industries in recent years. Within the U.S. several private rocket and space companies have launched and competed for highly lucrative contracts involving the delivery of satellites into space. Similar competition is occurring with regards to long range rockets that are eventually intended for lunar and inter-planetary travel. In addition to space-based interests in rockets, long running military interests in rockets have also significantly driven advancement in rocket science.

Existing rocket motor nozzle technologies typically consist of a machined or molded multi-piece design. This results in a relatively large part count and can require a specifically skilled labor force to manufacture assemble the parts, introducing costs and potential manufacturing flaws/challenges.

The area on the outside of the rocket motor nozzle, or “backside,” is not exposed directly to the combustion flames present inside the motor, but instead must remain at a low enough temperature not to damage the surrounding components, which often consist of sensitive electronics. Limiting this “backside nozzle peak temperature” while also minimizing weight, cost, and system size are typical design challenges in rocket motor nozzle design.

Rocket motors generate large amounts of thermal energy (heat), which the rocket motor nozzle must be able to withstand. Traditional rocket motor nozzles solve this challenge by “ablating” or absorbing the heat into sacrificial material such as graphite, carbon-carbon composite, or phenolic, rather than attempting to transfer the heat outward or control the flow of the heat away from specific areas of the rocket motor assembly.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

Disclosed embodiments include a computer system, for manufacturing a solid rocket motor nozzle using additive manufacturing, inputs into a temperature field algorithm, and at least one design parameter for the solid rocket motor nozzle. The computer system can generate, with the temperature field algorithm, a first temperature field for an initial solid rocket motor nozzle design using the at least one design parameter. Additionally, the computer system may provide the first temperature field for the initial solid rocket motor nozzle design to a nozzle-geometry optimization algorithm. The computer system then can generate, with the nozzle-geometry optimization algorithm, a first updated solid rocket motor nozzle design. The computer system can further generate, with the temperature field algorithm, a second temperature field for the first updated solid rocket motor nozzle design using the at least one design parameter. Additionally, the computer system may provide the second temperature field for the first updated solid rocket motor nozzle design to the nozzle-geometry optimization algorithm. The computer system then can generate, with the nozzle-geometry optimization algorithm, a second updated solid rocket motor nozzle design. Further, when the second updated solid rocket motor nozzle design meets a specified project requirement, the computer system can generate a file for additively manufacturing the second updated solid rocket motor nozzle design.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings.

FIG. 1 illustrates a schematic of a computer system for designing solid rocket motor nozzles.

FIG. 2 illustrates an embodiment of a solid rocket motor nozzle and multi-material throat.

FIG. 3 illustrates an embodiment of a lattice-Boltzmann optimized rocket nozzle and throat with a gyroid-pattern optimized infill and thermal barrier void space.

FIG. 4 illustrates a 3D Printed Gyroid Pattern.

FIG. 5 illustrates a flowchart for a method for manufacturing a solid rocket motor nozzle using additive manufacturing.

### DETAILED DESCRIPTION

Disclosed embodiments include a method for additively manufacturing insulation and mathematically optimizing a structure for an intended purpose. The method further comprises causing an additive manufacturing device to additively manufacture a gyroid structure conforming with the mathematically optimized structure. In some uses, the intended purposes is the design and manufacture of solid rocket motor nozzles. Accordingly, in at least one embodiment a solid rocket motor nozzle can be successfully designed, manufactured and test fired from 3D printed nozzles rather than traditional manufacturing techniques such as machining or molding.

Additively manufactured solid rocket motor nozzles enable the creation of tailored thermal profiles, support faster design cycles, and solve supply chain issues associated with traditional phenolic nozzles. Disclosed embodiments include the user of metal additive manufacturing for solid rocket motor nozzles and the ability to print multiple-materials into the structure of the nozzle design without requiring additional separate assembly steps. Additionally, disclosed embodiments include certain design features that can be used to create the thermal profile tailoring, higher performing, lower cost, or easier to produce nozzles. An advanced thermal analysis algorithm based on the lattice Boltzmann method (LBM) can be used to analyze the types of thermal flows found in complex geometry rocket motor nozzles.

Disclosed embodiments also include the use of multi-material printed nozzles, which have the potential to revolutionize printed rocket motor nozzles. Multi-material nozzles provide several benefits including higher temperature capability, lighter weight (resulting in longer ranges and higher speeds), lower cost, and reduced part count (resulting in lower assembly costs and risks). 3D printing also allows the manufacturing of new designs not capable of being manufactured via traditional manufacturing. For example new designs may include active cooling and other similar concepts.

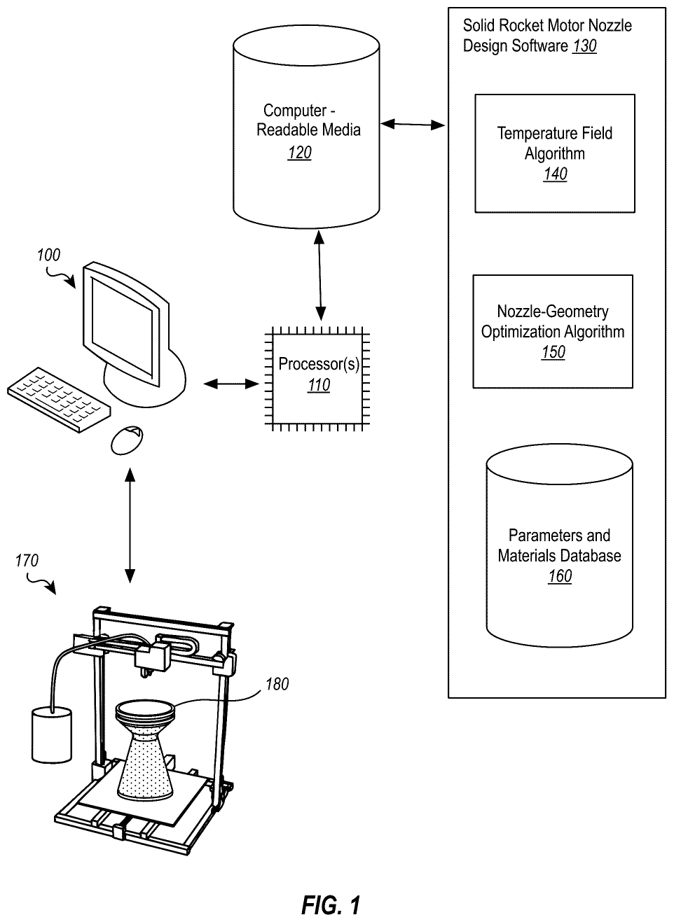

FIG. 1 illustrates a schematic of a computer system 100 for designing solid rocket motor nozzles 180. The depicted computer system 100 comprises one or more processors 110 and computer-readable media 120. The computer-readable media 120 stores executable instructions that when executed by the one or more processors configure the computer system 100 to execute a solid rocket motor nozzle design software application 130. The solid rocket motor nozzle design software application 130 comprises a temperature field algorithm 140, a nozzle-geometry optimization algorithm 150, and a parameters and materials database 160. The particulars and various examples of the temperature field algorithm 140 and the nozzle-geometry optimization algorithm 150 will be provided here.

In at least one embodiment, the computer system 100 inputs, into the temperature field algorithm 140, at least one design parameter for the solid rocket motor nozzle. The design parameters may comprise one or more of the following parameters: back-side temperature, front-side temperature, nozzle thickness, airspeed, nozzle material, altitude, ambient temperature, skin temperature of a motor, center of gravity, nozzle strength/stiffness, or weight target. Each of these parameters are well known to those having skill in the art as being parameters that can be considered during the design of a solid rocket motor nozzle.

As is described in greater detail below, the temperature field algorithm 140 generates a first temperature field for an initial solid rocket motor nozzle design using the at least one design parameter. The computer system 100 then provides the first temperature field for the initial solid rocket motor nozzle design to a nozzle-geometry optimization algorithm 150. As is described in greater detail below, the nozzle-geometry optimization algorithm 150 generates a first updated solid rocket motor nozzle design.

The computer system 100 may be configured to optimize a given design for a solid rocket motor nozzle by repeatedly generating updated temperature fields and updated solid rocket motor nozzle designs. For example, the temperature field algorithm 140 can generate a second temperature field for the first updated solid rocket motor nozzle design using the at least one design parameter. The computer system 100 provides the second temperature field for the first updated solid rocket motor nozzle design to the nozzle-geometry optimization algorithm 150. The nozzle-geometry optimization algorithm 150 generates a second updated solid rocket motor nozzle design 180. The computer system 100 may continually iterate through updated temperature fields and solid rocket motor nozzle designs until a project requirement is met.

When the second updated solid rocket motor nozzle design 180 meets a specified project requirement, the computer system 100 creates a file for additively manufacturing the second updated solid rocket motor nozzle design 180. The specified project requirement may be based upon the at least one design parameter. For example, the specified project requirement may comprise a particular front-side temperature requirement. Additionally or alternatively, the specified project requirement may also include aspects such as time requirements, cost requirements, and other similar requirements. For example, the solid rocket motor nozzle design software application 130 may be configured to account for a project deadline when iterating through various optimizations. This may include limiting the number of iterations based upon the time each iteration is taking in order to ensure the design is completed prior to the deadline.

In at least one embodiment, when the temperature field algorithm 140 generates a temperature field, the temperature field algorithm 140 generates multiple different temperature fields for the solid rocket motor nozzle design using different design parameters for each of the multiple different temperature fields. The different design parameters may comprise boundary parameters based upon the at least one design parameter. For example, the temperature field algorithm 140 may generate a temperature field for a design parameter for the thinnest allowable walls of the solid rocket motor nozzle design. The temperature field algorithm 140 may also generate a temperature field for a design parameter for the thickest allowable walls of the solid rocket motor nozzle design. Similarly, the temperature field algorithm 140 may use design parameters for different airspeeds, different altitudes, stiffnesses, etc. The temperature field algorithm 140 may then combine the multiple different temperature fields into a single first temperature field for the solid rocket motor nozzle design.

In at least one embodiment, the nozzle-geometry optimization algorithm 150 can generate a solid rocket motor nozzle design by selecting one or more materials from a list of available materials. The list of materials may comprise a dataset in the parameters and materials database 160. The one or more materials may be selected based at least in part upon a temperature field of a previous design.

Additionally, in at least one embodiment, the nozzle-geometry optimization algorithm 150 can generate g-code or some other code for actuating an additive manufacturing process. For example, the nozzle-geometry optimization algorithm 150 may generate a g-code file for 3D printing the solid rocket motor nozzle design. In at least one embodiment, the nozzle-geometry optimization algorithm 150 can create commands within the file to additively manufacture the solid rocket motor nozzle design using the one or more materials. By way of example and not limitation, the one or more materials may comprise different metals, ceramics, insulators such as composites, resins, plastics or phenolic materials.

The nozzle-geometry optimization algorithm 150 may also be capable of creating an additive manufacturing file for additively manufacturing gyroid-pattern insulation for the solid rocket motor nozzle design. As explained further below, the gyroid-pattern insulation may provide unique benefits within a solid rocket motor nozzle design. Further, the additive manufacturing may provide a novel avenue for printing gyroid-pattern insulation.

Further, in at least one embodiment, the nozzle-geometry optimization algorithm 150 may also be capable of creating a file for additively manufacturing active or passive cooling channels within the solid rocket motor nozzle design. Additionally or alternatively, the nozzle-geometry optimization algorithm 150 may also be capable of creating a file for additively manufacturing thermal energy management ducts within the solid rocket motor nozzle design. As is explained further below, the active or passive cooling channels or thermal energy management ducts may be built into the structure of the solid rocket motor nozzle design in order to provide more cooling to the solid rocket motor nozzle design. In at least one embodiment, the temperature field algorithm 140 is configured to account for the presence and location of active or passive cooling channels or thermal energy management ducts when creating a temperature field.

Additionally, disclosed embodiments include the manufacture of solid rocket nozzles via a process that includes topology optimization. For example, in at least one embodiment the temperate field algorithm 140 applies the LBM analysis to thermal protection structures, including those found in rocket motor models. The 3D printed nozzles may have multiple benefits over conventional phenolic nozzles, including at least: (1) more-tailored thermal management, by re-directing heat around sensitive areas on the back side of the nozzle, (2) reduced supply chain challenges, particularly those associated with assembly labor, shrinking resin industrial base, and material lead times, and (3) faster design and R&D cycles, enabling the final product to contain a more-optimized nozzle and achieve greater range for the missile. In some embodiments, a designer may be able to obtain solid rocket motor nozzles less than one month after ordering (versus phenolic nozzles, which could take 12-18 months). Disclosed embodiments also improve high-speed, high-temperature flow modeling via several avenues, including adding radiation effects to the model and exploring an enthalpy method to model melting and ablation on the inside surface of the nozzle. Additionally disclosed embodiments parallelize the lattice Boltzmann method (LBM) software for faster execution.

The temperature field algorithm 140, in the form of lattice Boltzmann methods, arise as minimally discretized numerical schemes of the Boltzmann transport equation (BTE). The method includes the evolution of the distribution of the particle populations by a collision step, which is then followed by their lock-step advection along discrete directions, referred to as the streaming step. The former is often modeled by a relaxation to equilibria. The discrete particle velocity directions are referred to as the lattice, which obeys the associated physical symmetry and isotropy of the fluid flow and/or energy transport being simulated. The macroscopic fields such as the fluid velocity and the temperature are obtained from the averaged representation of the particle transport in terms of their distribution functions, i.e., using their velocity moments. As such the LBM is characterized as a mesoscopic approach and have the following unique features and advantages compared to the more convectional computational methods. Its streaming step is linear and exact, and all nonlinearity is modeled locally in the collision step; by contrast, the convective term in the continuum representation of the fluid motion, i.e., the Navier-Stokes equations, is nonlinear and nonlocal. As a result, the pressure field is obtained locally in the LB methods, circumventing the need for the solution of the time-consuming elliptic Poisson equation as in traditional methods. The exact advection in the streaming step combined with the collision step based on a relaxation model leads to a second order accurate method with relatively low numerical dissipation. The kinetic model for the collision step can be tailored to introduce additional physics as necessary and its additional degree of freedom can be tuned to improve numerical stability. The locality of the steps in the LBM makes it amenable for almost ideal implementation on parallel computers for efficient large scale flow simulations. Moreover, various boundary conditions for complex geometries can be represented readily using relatively simple rules for the particle populations, thereby avoiding time-consuming grid generation associated with the conventional approaches.

The LBM use in the simulations of thermal systems in the last decade can generally be categorized as either based on multiple particle speed formulation, hybrid approach or double distribution functions (DDF), with the latter being the most widely used. In the DDF-LBM approaches, one distribution function is used to compute the flow field and the other the temperature field. In at least one embodiment, a novel DDF-LBM based on the so-called cascaded central moments results in robust and stable simulations for a wider range of conditions and properties than other existing LBM approaches. In addition, the LBM has shown to be promising for handling conjugate heat transfer problems involving assorted solid structures embedded within or enclosing fluid flows. The LBM may be capable of accurately modeling and simulating the thermal transport through additively manufactured porous metallic structures with complex topologies. Disclosed embodiments utilize LBM to provide field-driven simulation results for thermal optimization of 3D printed nozzles using the nTopology software.

As disclosed above, the temperate field algorithm 140 may comprise algorithms based upon the lattice Boltzmann method (LBM). For example the temperate field algorithm 140 may comprise a Discrete Unified Gas Kinetic Scheme (DUGKS) that can be used to solve the Boltzmann equation for representing high-speed, compressible (supersonic) and high-temperature gas flow through the nozzle, including shock discontinuity effects. This may provide improved abilities to represent the effect of gas flow, where conventional methods utilize a highly simplified convective heat transfer correlation available in the literature. Implementation of the proposed improved approach given below will represent more realistic effects of the gas flow, which effectively provides the heat fluxes to the interior surface of the nozzle as input during the burn time, which will then be integrated into the temperature field algorithm 140 for prediction of the temperature field within the solid material of the nozzle. Since the LBM is based on the Boltzmann equation, just like the proposed GKM, the overall approach, then will result in a unified and physically consistent framework which is applicable for a broad range of conditions.

Additionally, the temperate field algorithm 140 may comprise a unified gas kinetic scheme (UGKS), which is a dynamical multiscale method applicable for a wide range of flow speeds, from subsonic through hypersonic flows, and encompassing a wide range of scales, from continuum to rarefied flow regimes. The UGKS is based on an explicit finite volume method for solving the Boltzmann equation involving a coupling of the particle transport with collision for computing the fluxes across the computational cell interfaces, where the time step is independently adjustable from the relaxation time parameter for collision. The discrete unified gas kinetic scheme (DUGKS) may comprise an improvement and simplification of the UGKS. The UGKS is based on a local integral solution of the Boltzmann equation for flux evaluation at the cell interfaces, where an update of the macroscopic variables is required with attendant additional computational costs. By contrast, in the DUGKS, the update of the macroscopic state of the gas flow is based on the evolution of a modified distribution function rather than the original variable, with variable transformations utilized to remove implicit treatment of the collision term, and the flux evaluations at cell interfaces are based on a simplified reconstruction using an averaging procedure on the directions of particle characteristics. It does not require an evolution of the macroscopic variables at cell interfaces and the discretization of the particle velocities are flexible according to the range of speeds of gas flow being modeled. For simulating non-equilibrium flows at high Mach numbers with strong variations in temperature, which arise in gas flow through the nozzle during the burn phase, a Shakhov kinetic model for collision is used.

In at least one embodiment, a proposed DUGKS is expected to perform such simulations more efficiently. Since both DUGKS and LBM are formulated from Boltzmann equations, such coupling between these two schemes for simulating the thermal fields at different regions is expected to be natural and seamless.

Disclosed embodiments of DUGKS may utilize an open source library dugksFoam, which is written as part of the open source computational fluid dynamics (CFD) package OpenFOAM (an acronym which stands for Open-source Field Operation And Manipulation) using the C++ language. DUGKS, like the LBM, scales well on parallel computer cluster, which is very helpful for delivering fast simulations. In at least one embodiment, the temperate field algorithm 140 code has been written in the C++ language, the integration and interfacing of the two codes can be naturally accomplished.

Disclosed embodiments consider thermal conduction and convection as the two modes of heat transfer through the nozzle surfaces. When the propellant inside the nozzle undergoes combustion, it heats up the nozzle to relatively high temperatures, at which thermal radiation effects could be significant. Thus, in order to improve the accuracy of prediction under high temperature conditions, disclosed embodiments incorporate such a third mode of heat transfer within a simulation modeling framework. This can be accomplished using the Stefan-Boltzmann law for thermal radiation, where the emissivity coefficient is used to account for the actual surface properties of the nozzle material. As a result, the total heat fluxes across the interior and exterior surfaces of the nozzle are the sum of heat flux due to convection (modeled via the Newton's law of cooling) and radiation (prescribed by the Stefan-Boltzmann's law). They can be expressed as follows:

$$- {{k}_{s} ( \frac{\partial T}{\partial n} )}_{surf , int} = {h}_{int} ( {T}_{g , avg} - {T}_{surf , int} ) + εσ ( {T}_{g , avg}^{4} - {T}_{surf , int}^{4} ) , \qquad ( Equation 1 )$$

$$- {{k}_{s} ( \frac{\partial T}{\partial n} )}_{surf , ext} = {h}_{ext} ( {T}_{surf , ext} - {T}_{a} ) + ε σ ( {T}_{surf , ext}^{4} - {T}_{a}^{4} ) , \qquad ( Equation 2 )$$

where the subscripts ‘surf, int’ and ‘surf, ext’ refer to interior and exterior nozzle surfaces, respectively, and a is the Stefan-Boltzmann's constant. Here, hᵢₙₜ and hₑₓₜ are the convective heat transfer coefficients at the inner and outer surfaces, respectively, ε is the thermal emissivity coefficient of the nozzle material, g_{g,avg} is the average of the hot, exhaust gas temperature at a given location along the length of the nozzle, Tₐ is the ambient air temperature of the surroundings. Disclosed embodiments may use simplified thermodynamical considerations and semi-empirical correlations for estimating the averaged burnt hot gas temperature heat transfer coefficients due to forced convection. Additionally or alternatively, the simplified considerations may be replaced with and more accurately and self-consistently modeled using the results from the simulations of DUGKS outlined above. Similarly, the boundary condition at the exterior nozzle surface can be implemented to account for the more general thermal radiation effects for improving the predication from simulations for field-driven optimization of 3D printed nozzles.

Results from nozzle tests for both the baseline and optimized designs performed during experiments indicated significant melting/ablation on their interior surfaces during the burn times. Such phase transformations could have significant impact on the overall thermal fields generated in the nozzle. Disclosed embodiments of the temperature field algorithm 140 include a model to account for the phase change effects involving melting/ablation during the burn times via an Enthalpy method, which will be integrated within the temperature field algorithm 140 to simulate and investigate such effects systematically.

The enthalpy method was developed for handling solid-liquid phase transitions, with the initial applications focusing on problems related to metallurgy, such as metal casting. In essence, the Enthalpy method involves tracking the total enthalpy H, which is the sum of the sensible heat CₚT and the latent heat Lφₗ due to phase change in a computational cell, and can be written as H=CₚT+Lφᵢ, where Cₚ is the specific heat capacity and L is the latent heat of melting of the material undergoing phase change, and φₗ is the liquid or melt fraction, with φₗ=1 for melt (liquid) phase and φₗ=0 for the solid phase. The evolution equation of the total enthalpy reads as

δₜH+∇·(CₚTu)=∇·((λ/ρ₀)∇T) (Equation 3)

where λ and ρ represent the thermal conductivity and reference density, respectively. Solution of Eq. (3) yields the local value of the total enthalpy H from which the state of phase transformation, i.e., the extent of melt formation and the temperature for each computational cell can be determined. In particular, the local melt fraction φₗ and the temperature T based on H can be calculated as follows:

$${φ}_{l} = \{ \begin{matrix}0 , & H \leq {H}_{s} \\ \frac{H - {H}_{s}}{{H}_{l} - {H}_{s}} , & {H}_{s} < H < {H}_{l} \\ 1 , & H \geq {H}_{l}\end{matrix} \qquad ( Equation 4 )$$

$$T = \{ \begin{matrix}{T}_{s} - ( \frac{{H}_{s} - H}{{c}_{p , s}} ) , & H \leq {H}_{s} \\ ( \frac{{H}_{l} - H}{{H}_{l} - {H}_{s}} ) {T}_{s} + ( \frac{H - {H}_{s}}{{H}_{l} - {H}_{s}} ) {T}_{l} , & {H}_{s} < H < {H}_{l} \\ {T}_{l} + ( \frac{H - {H}_{l}}{{c}_{p , l}} ) , & H \geq {H}_{l}\end{matrix}$$

Equation (4) involves a number of thermophysical properties, which are known for a chosen material of the nozzle.

For the purpose of illustration, we now present a simple formulation of the LB scheme, which can be written as

$${ℊ}_{α} ( x + {e}_{α} , t + {δ}_{t} ) - {ℊ}_{α} ( x , t ) = \frac{1}{{τ}_{T}} [ {ℊ}_{α}^{eq} ( x , t ) - {ℊ}_{α} ( x , t ) ] , \qquad ( Equation 5 )$$

where the equilibrium distribution function gₐ^{eq} is given by

$${ℊ}_{α}^{eq} = \{ \begin{matrix}H - {\tilde{C}}_{p} T + {w}_{α} {C}_{p} T [ {\tilde{C}}_{p} / {C}_{p} - I : uu / ( 2 {c}_{s}^{2} ) ] , & α = 0 \\ {w}_{α} {C}_{p} T [ {\tilde{C}}_{p} / {C}_{p} + {e}_{α} \cdot u / {c}_{s}^{2} + ( ( {e}_{α} {e}_{α} - {c}_{s}^{2} I ) : uu ) / ( 2 {c}_{s}^{4} ) ] , & a \neq 0\end{matrix}$$

Here, \tilde{C}ₚ is a reference specific heat given by the following harmonic mean between the solid and the melt phases \tilde{C}ₚ=2C_{p,s}C_{p,l}/(C_{p,s}+C_{p,l}), and the relaxation time τ_{T} in the LB scheme in Eq. (20) can be related to the local thermal conductivity and the reference specific capacity via τ_{T}=3+λ/(ρ₀\tilde{C}ₚ). Solving Eq. (5) by the collision and streaming steps, we can then obtain the local total enthalpy H at each grid node as the zeroth moment of the distribution function gₐ, i.e., its summation over all discrete velocity directions:

H=Σₐgₐ. (Equation 6)

Disclosed embodiments include temperature field algorithm 140 that incorporate the Enthalpy method using the more robust collision models developed to model and simulate the unique ablation phenomenon occurring during the burn phase transients of the rocket nozzles.

To develop a baseline lattice Boltzmann method simulation, disclosed embodiments apply the appropriate boundary conditions to the nozzle that would result in a temperature field that is congruent with the baseline physical experiment. To do this, an experiment simulated the motor and nozzle, extracting temperatures at the identical locations as the thermocouples in the baseline experiment. The experiment compared the temperatures from the simulation with those of the thermocouple readings by plotting them on the same graph and then iterating with different boundary conditions until the temperature profiles match more nearly. This is referred to as the “baseline simulation” because it is based on the un-optimized nozzle used in the baseline physical experiment. Once the temperature profiles were relatively close, the solid rocket motor nozzle design software 130 can design an optimized nozzle by running simulations using the same boundary conditions as those of the baseline simulation case and observing changes to the results relative to the baseline case.

To begin this process, the software 130 considers that the boundary on the outside of the nozzle is losing heat by convection to the outside air. In contrast, the boundary on the inside of the nozzle is being heated by hot flowing gas. The outer boundary condition here is defined as

$$- k \frac{\partial T}{\partial n} {\vert}_{wall} = {h}_{air} ( {T}_{wall} - {T}_{∞} ) ,$$

where the heat transfer by convection coefficient is assumed to be hₐᵢᵣ=25 W/m²K, which is on the upper end of commonly found values for convection heat transfer with air as the working fluid. The inner boundary condition is similar; however, we consider that hot gas is transferring heat to the solid wall instead of carrying heat away from it. This condition is defined as

$$- k \frac{\partial T}{\partial n} {\vert}_{wall} = {h}_{hot gas} ( {T}_{hot gas} - {T}_{wall} ) ,$$

and is applied for the duration that the propellant is burning, and then is changed to match that of the outer boundary condition after the propellant stops burning. The inner boundary condition during the time when propellant is burning requires two unknown properties. Namely, the software 130 provides an estimate for both the hot gas temperature, T_{hot gas}, and the heat transfer by convection coefficient for the hot gas, h_{hot gas}. Here, the hot gas temperature is not constant through the nozzle in the flow direction as it expands from high pressure inside the nozzle to the atmospheric pressure at the nozzle exit.

Then, to further estimate the changes in gas temperature along the flow direction, the software 130 takes the maximum temperatures from each thermocouple, creates a temperature profile, and normalizes it with the estimated maximum gas temperature. Using these temperatures, a fifth-order polynomial curve fit may be performed and then used as the hot gas temperature along the length of the nozzle in the flow direction, down from the nozzle throat, where the maximum temperature is assumed to be located. This fifth-order polynomial curve fit is defined as T(z)=c₁z⁵+c₂z⁴+c₃z³+c₄z²+c₅z+c₆

Next, an estimate for the hot gas heat transfer coefficient by convection is created for the inner boundary condition for the duration of the motor firing. To do this, the temperature field algorithm 140 employs a model developed by Sleicher and Rouse and reported in ‘Convective Heat and Mass Transfer’ by W. M. Krays and M. E. Crawford; this model is suggested for large Prandtl number and large Reynolds number flows and given as

$$Nu = \frac{hD}{k} = 5 + 0.0 \; 15 * {Re}^{a} * {Pr}^{b} ,$$

$$where a = 0.88 - \frac{0.24}{4 + P r} , and$$

$$b = 0. 333 + 0.5 {e}^{- 0.6 Pr} .$$

The temperature field algorithm 140 estimates the gas velocity to approximate the Reynolds number. To do this, the temperature field algorithm 140 uses a control volume analysis for the conservation of momentum for the flow through the nozzle. Using the resulting heat transfer coefficient from these simulations, the temperature field algorithm 140 may be able to obtain a simulated result that correlates well with the baseline experimental firing data. In other words, the magnitude of the maximum temperatures and the cooling rates are similar enough to run simulations on an optimized set of nozzles, for which the temperature field algorithm 140 can compare the same results relative to the simulation baseline case.

Disclosed embodiments include an optimized nozzle where a gyroid lattice structure will be used on the outer surface of the nozzle, which will remove mass as well as increase the surface area of the outer boundary. In turn, the outside of the nozzle will have a larger surface area from which heat will be removed by convection, and the nozzle will thus cool more quickly. On the other hand, because there is less mass, the heat will transfer through the nozzle by conduction more quickly and will have hotter maximum temperatures overall. This design aims to find a balance between having faster cooling rates and minimizing the peak temperatures.

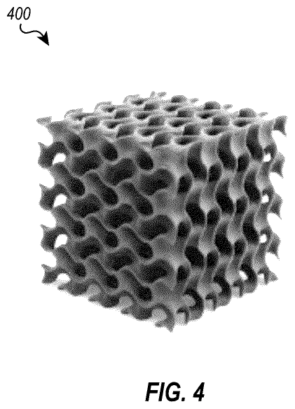

In at least one embodiment, a gyroid lattice 400 is used (e.g., FIG. 4). By varying the cell size and thickness of the lattice, the temperature field algorithm 140 is able to identify which features can be exploited to achieve the fastest cooling rates and minimize peak temperatures. To begin these efforts, five different optimized nozzles were generated in nTopology (nTop) and used in the LBM simulations. First, the cell spacing of the gyroids was set at 5, 7.5, and 10 mm using a wall thickness of 1.5 mm. Next, the wall thickness was varied across 1.0, 1.5, and 2.0 mm using a cell spacing of 7.5 mm. In all models, the lattice was uniform. In a later step, simulation results may be used to tailor the wall thickness of the gyroid lattice. Other TPMS structures can be incorporated within the nozzle design, such as Swarzs, Diamond, Lininoid, SplitP, and Neovius. While the high surface area of TPMS structures can be desirable for heat transfer applications, disclosed embodiments are not limited to these architectures. Other lattice structures used for lightweight mechanical reinforcement include tetrahedral, octet, and honeycomb lattices.

The results from these five cases all indicate that applying the lattice structure significantly increases the cooling rate of the nozzle but also that a lattice structure with more mass will have a lower maximum temperature. This cooling rate increase from the hollow structure could be applied in a future design that channels external air through the nozzle structure to increase cooling rate further and reduce the required nozzle thickness. Alternatively, these spaces could be filled with a resin, vacuum, or another printed material to further reduce heat transfer in a non-vented structure.

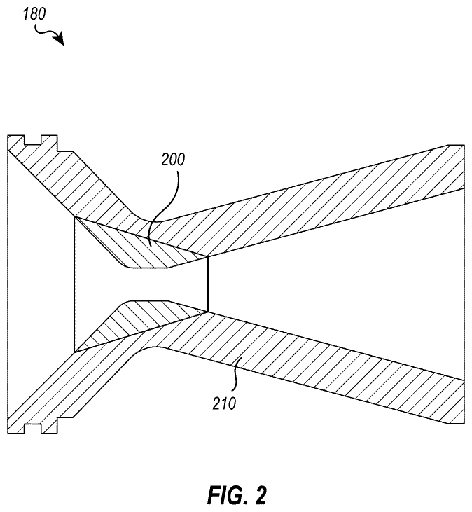

To further extend the optimized nozzle design, a field-driven nozzle design may be applied by a computer-aided design software package, such as nTopology provided by nTopology Inc. located in New York, NY. One of skill in the art will appreciate that various different software suites may be utilized for the optimization and generation of CAD files and/or additive manufacturing files. As such, the present invention is not so limited to a particular software suite for use as a nozzle-geometry optimization algorithm 150. A temperature point map of the simulation results may be imported into a nozzle-geometry optimization algorithm 150 and a temperature field may be overlayed to the gyroid design. A ramp function may be used to tailor the wall thickness and was varied along both the length of the nozzle and in the radial direction. The hottest region of the nozzle may be near the throat and near the inside boundary, while the coolest part may be near the exit and on the outside boundary. As depicted in FIG. 2, a lattice structure may be tailored such that there is more mass near the nozzle throat 200 and near the inside radially, and less mass near the exit 210 and near the outside boundary in the radial direction. In at least one embodiment, the throat 200 may comprise a different material than the exit 210. For example, the throat 200 may comprise a denser or more heat resistant material, while the exit 210 may comprise a less dense lighter material.

The results from the field-driven design indicated a slightly lower maximum temperature and a slightly faster cooling rate. In this regard, the field-driven design process was shown to be a tool that can further optimize the nozzles cooling properties.

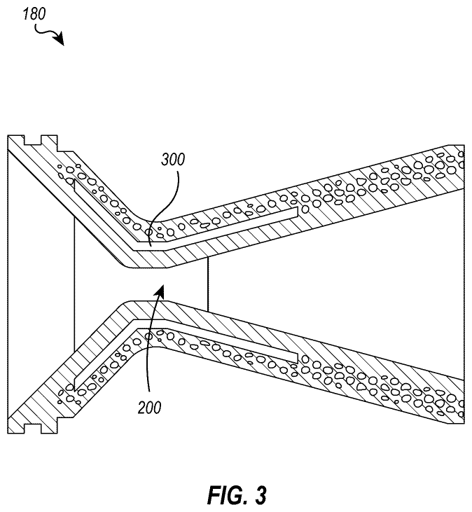

To further control the temperature on the outside of the nozzle 180, especially in specific regions, disclosed embodiments add a very thin and completely enclosed gap of air 300 to the inside of the nozzle. In FIG. 3, the nozzle-geometry optimization algorithm 150 does this starting at just above the nozzle throat 200 and extend this gap down. Air has relatively minimal thermal conductivity. If the gap of air 300 is kept thin enough, the air will not be able to move around via natural convection inside the gap. In this regard, it is kept stationary and can be modeled like a solid body that transfers heat by conduction. On the other hand, the gap of air 300 could be filled by another solid material, such as a phenolic-type resin material. In any event, the gap 300 would serve as an insulator that will redirect the heat transfer around the gap and thus keep the region directly behind the gap on the outside of the nozzle from heating up as much.

FIG. 4 illustrates thermal energy management ducts in the form of active or passive cooling channels (similar to NACA duct inlets) on the outer skin of the airframe of the missile, that would allow air external air to be routed through the lattice structures of the nozzles (the gyroid structures tend to have a continuous air volume throughout, rather than isolated air pockets that would make active air cooling difficult, such as those found in cubic lattice structures). Thermal energy management can take the form of organizing the geometry and material layout within the part to create paths that are either more or less conducive for thermal energy to travel along. These paths can take the form of ducts (which present additional resistance to thermal energy migration by incorporating lower conductivity materials), active cooling channels (which encourage cooling by allowing in outside air or another cooling medium) or passive cooling channels (similar to active cooling but without the pressure differential that drives the flow of cooling medium on an active channel).

The computational cost of solving large size problems is very high and it demands high-speed processors and large memory in the system. The modern multi-core processors can perform several computations in parallel, known as parallel processing, which can be used to reduce the computation time dramatically. One of the main advantages of the LBM is its natural parallelization capabilities due to the locality of its algorithm, which can be exploited for efficient simulations when implemented on HPC platforms.

During experimental testing involving the initial feasibility of the 3 temperature field algorithm 140 for field-driven simulations for the nozzle, the system was implemented on a single CPU machine, and each case study to predict thermal fields within the nozzle geometry typically required several days of computation time. Disclosed embodiments will be significantly faster and a near-linear speed up. Disclosed embodiments parallelize the temperature field algorithm 140 using the Message Passing Interface (MPI) library that implements the domain decomposition strategy and allocates different processes to each subdomain while facilitating the inter-process communications. In addition, all the other codes resulting from the proposed modeling improvements, such as the DUGKS for high-speed/high-temperature gas flow and the 3D enthalpy LBM for modeling ablation/melting effects, will also be parallelized.

The following discussion now refers to a number of methods and method acts that may be performed. Although the method acts may be discussed in a certain order or illustrated in a flow chart as occurring in a particular order, no particular ordering is required unless specifically stated, or required because an act is dependent on another act being completed prior to the act being performed.

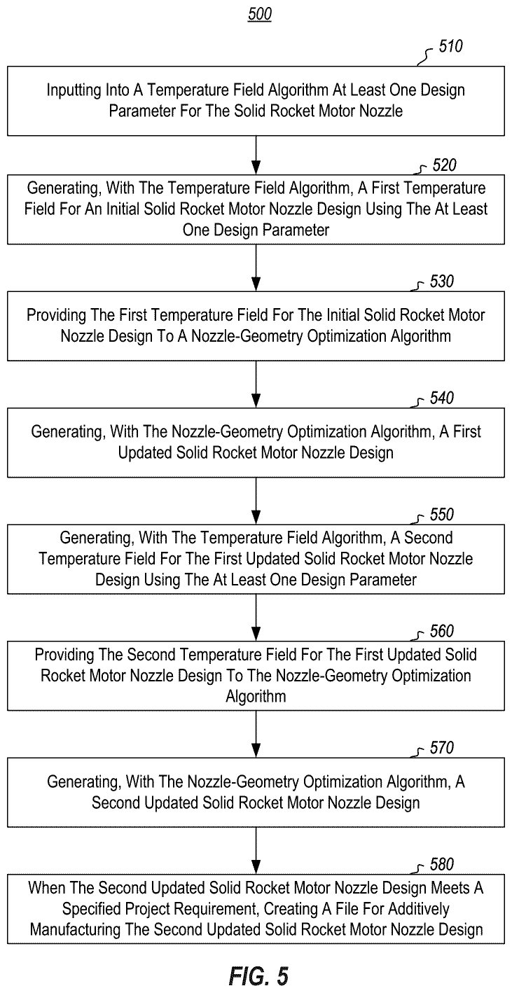

FIG. 5 is a flowchart of an example method 500 for manufacturing a solid rocket motor nozzle using additive manufacturing. Method 500 comprises a step 510 of inputting into a temperature field algorithm 140 at least one design parameter for the solid rocket motor nozzle. For example, the temperature field algorithm 140 may receive a design parameter relating to the sizes of the solid rocket motor nozzle.

Method 500 also includes a step 520 of generating, with the temperature field algorithm 140, a first temperature field for an initial solid rocket motor nozzle design using the at least one design parameter. For example, the temperature field algorithm 140 may utilizes a LBM to generate a temperature map of the initial solid rocket motor nozzle design.

Additionally, method 500 includes a step 530 of providing the first temperature field for the initial solid rocket motor nozzle design to a nozzle-geometry optimization algorithm 150. For example, as explained above, a software package such as nTopology may be used as a nozzle-geometry optimization algorithm 150 that can receive the temperature field and optimize an initial rocket motor nozzle design.

Method 500 may then include a step 540 for generating, with the nozzle-geometry optimization algorithm 150, a first updated solid rocket motor nozzle design. As explained above, the nozzle-geometry optimization algorithm 150 may generated an updated solid rocket motor nozzle design based upon its processing of the temperature field and the initial solid rocket motor nozzle design.

In addition method 500 may include a step 550 for generating, with the temperature field algorithm 140, a second temperature field for the first updated solid rocket motor nozzle design using the at least one design parameter. As explained above, the software 130 may iterate through different models by generating temperature fields, generating updated solid rocket motor nozzle designs, and repeating the process.

For example, method 500 includes a step 560 of providing the second temperature field for the first updated solid rocket motor nozzle design to the nozzle-geometry optimization algorithm 150. Similar to above, the nozzle-geometry optimization algorithm 150 can process the updated temperature field and generated another updated solid rocket motor nozzle design.

Further, method 500 includes a step 570 of generating, with the nozzle-geometry optimization algorithm 150, a second updated solid rocket motor nozzle design. For example, similar to step 540 above the nozzle-geometry optimization algorithm 150 may generated an updated solid rocket motor nozzle design based upon its processing of the temperature field and the initial solid rocket motor nozzle design.

Further still, method 500 includes a step 580 of, when the second updated solid rocket motor nozzle design meets a specified project requirement, creating a file for additively manufacturing the second updated solid rocket motor nozzle design. For example, the nozzle-geometry optimization algorithm 150 may be configured to generate g-code for an optimized solid rocket motor nozzle design.

Further, the methods may be practiced by a computer system including one or more processors and computer-readable media such as computer memory. In particular, the computer memory may store computer-executable instructions that when executed by one or more processors cause various functions to be performed, such as the acts recited in the embodiments.

Computing system functionality can be enhanced by a computing systems' ability to be interconnected to other computing systems via network connections. Network connections may include, but are not limited to, connections via wired or wireless Ethernet, cellular connections, or even computer to computer connections through serial, parallel, USB, or other connections. The connections allow a computing system to access services at other computing systems and to quickly and efficiently receive application data from other computing systems.

Interconnection of computing systems has facilitated distributed computing systems, such as so-called “cloud” computing systems. In this description, “cloud computing” may be systems or resources for enabling ubiquitous, convenient, on-demand network access to a shared pool of configurable computing resources (e.g., networks, servers, storage, applications, services, etc.) that can be provisioned and released with reduced management effort or service provider interaction. A cloud model can be composed of various characteristics (e.g., on-demand self-service, broad network access, resource pooling, rapid elasticity, measured service, etc.), service models (e.g., Software as a Service (“SaaS”), Platform as a Service (“PaaS”), Infrastructure as a Service (“IaaS”), and deployment models (e.g., private cloud, community cloud, public cloud, hybrid cloud, etc.).

Cloud and remote based service applications are prevalent. Such applications are hosted on public and private remote systems such as clouds and usually offer a set of web based services for communicating back and forth with clients.

Many computers are intended to be used by direct user interaction with the computer. As such, computers have input hardware and software user interfaces to facilitate user interaction. For example, a modern general purpose computer may include a keyboard, mouse, touchpad, camera, etc. for allowing a user to input data into the computer. In addition, various software user interfaces may be available.

Examples of software user interfaces include graphical user interfaces, text command line based user interface, function key or hot key user interfaces, and the like.

Disclosed embodiments may comprise or utilize a special purpose or general-purpose computer including computer hardware, as discussed in greater detail below. Disclosed embodiments also include physical and other computer-readable media for carrying or storing computer-executable instructions and/or data structures. Such computer-readable media can be any available media that can be accessed by a general purpose or special purpose computer system. Computer-readable media that store computer-executable instructions are physical storage media. Computer-readable media that carry computer-executable instructions are transmission media. Thus, by way of example, and not limitation, embodiments of the invention can comprise at least two distinctly different kinds of computer-readable media: physical computer-readable storage media and transmission computer-readable media.

Physical computer-readable storage media includes RAM, ROM, EEPROM, CD-ROM or other optical disk storage (such as CDs, DVDs, etc.), magnetic disk storage or other magnetic storage devices, or any other medium which can be used to store desired program code means in the form of computer-executable instructions or data structures and which can be accessed by a general purpose or special purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmissions media can include a network and/or data links which can be used to carry program code in the form of computer-executable instructions or data structures and which can be accessed by a general purpose or special purpose computer. Combinations of the above are also included within the scope of computer-readable media.

Further, upon reaching various computer system components, program code means in the form of computer-executable instructions or data structures can be transferred automatically from transmission computer-readable media to physical computer-readable storage media (or vice versa). For example, computer-executable instructions or data structures received over a network or data link can be buffered in RAM within a network interface module (e.g., a “NIC”), and then eventually transferred to computer system RAM and/or to less volatile computer-readable physical storage media at a computer system. Thus, computer-readable physical storage media can be included in computer system components that also (or even primarily) utilize transmission media.

Computer-executable instructions comprise, for example, instructions and data which cause a general purpose computer, special purpose computer, or special purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Those skilled in the art will appreciate that the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, and the like. The invention may also be practiced in distributed system environments where local and remote computer systems, which are linked (either by hardwired data links, wireless data links, or by a combination of hardwired and wireless data links) through a network, both perform tasks. In a distributed system environment, program modules may be located in both local and remote memory storage devices.

Alternatively, or in addition, the functionality described herein can be performed, at least in part, by one or more hardware logic components. For example, and without limitation, illustrative types of hardware logic components that can be used include Field-programmable Gate Arrays (FPGAs), Program-specific Integrated Circuits (ASICs), Program-specific Standard Products (ASSPs), System-on-a-chip systems (SOCs), Complex Programmable Logic Devices (CPLDs), etc.

The present invention may be embodied in other specific forms without departing from its spirit or characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A computer system for manufacturing a solid rocket motor nozzle using additive manufacturing, the computer system comprising:
one or more processors; and
one or more computer-readable media having stored thereon executable instructions that when executed by the one or more processors configure the computer system to at least:
input into a temperature field algorithm at least one design parameter for the solid rocket motor nozzle;
generate, with the temperature field algorithm, a first temperature field for an initial solid rocket motor nozzle design using the at least one design parameter;
provide the first temperature field for the initial solid rocket motor nozzle design to a nozzle-geometry optimization algorithm;
generate, with the nozzle-geometry optimization algorithm, a first updated solid rocket motor nozzle design;
generate, with the temperature field algorithm, a second temperature field for the first updated solid rocket motor nozzle design using the at least one design parameter;
provide the second temperature field for the first updated solid rocket motor nozzle design to the nozzle-geometry optimization algorithm;
generate, with the nozzle-geometry optimization algorithm, a second updated solid rocket motor nozzle design; and
when the second updated solid rocket motor nozzle design meets a specified project requirement, create a file for additively manufacturing the second updated solid rocket motor nozzle design.

2. The computer system as recited in claim 1, wherein the temperature field algorithm comprises a lattice-Boltzmann method.

3. The computer system as recited in claim 1, wherein the executable instructions for generating the first temperature field for the initial solid rocket motor nozzle design include instructions that are executable to configure the computer system to:
generate multiple different temperature fields for the initial solid rocket motor nozzle design using different design parameters for each of the multiple different temperature fields; and
combine the multiple different temperature fields into a single first temperature field for the initial solid rocket motor nozzle design.

4. The computer system as recited in claim 3, wherein the different design parameters comprise boundary parameters based upon the at least one design parameter.

5. The computer system as recited in claim 1, wherein creating the file for additively manufacturing the second updated solid rocket motor nozzle design comprises creating commands to additively manufacture gyroid-pattern insulation.

6. The computer system as recited in claim 1, wherein creating the file for additively manufacturing the second updated solid rocket motor nozzle design comprises creating commands to additively manufacture active or passive cooling channels within the second updated solid rocket motor nozzle design.

7. The computer system as recited in claim 1, wherein creating the file for additively manufacturing the second updated solid rocket motor nozzle design comprises creating commands to additively manufacture thermal energy management ducts within the second updated solid rocket motor nozzle design.

8. The computer system as recited in claim 1, wherein creating the file for additively manufacturing the second updated solid rocket motor nozzle design comprises creating commands to additively manufacture insulators such as composites, resins, plastics, or phenolic materials within the second updated solid rocket motor nozzle design.

9. The computer system as recited in claim 1, wherein the executable instructions include instructions that are executable to configure the computer system to:
generate the second updated solid rocket motor nozzle design comprises selecting one or more materials from a list of available materials to utilize when generating the second updated solid rocket motor nozzle design, wherein the one or more materials are selected based at least in part upon the second temperature field; and
creating commands within the file to additively manufacture the second updated solid rocket motor nozzle design using the one or more materials.

10. The computer system as recited in claim 9, wherein the one or more materials comprise different metals, ceramics, insulators such as composites, resins, plastics or phenolic materials.

11. The computer system as recited in claim 1, wherein the at least one design parameter comprises one or more of the following parameters: back-side temperature, front-side temperature, nozzle thickness, airspeed, nozzle material, altitude, ambient temperature, skin temperature of a motor, center of gravity, nozzle strength/stiffness, or weight target.

12. A method for manufacturing a solid rocket motor nozzle using additive manufacturing, the method comprising:
inputting into a temperature field algorithm at least one design parameter for the solid rocket motor nozzle;
generating, with the temperature field algorithm, a first temperature field for an initial solid rocket motor nozzle design using the at least one design parameter;
providing the first temperature field for the initial solid rocket motor nozzle design to a nozzle-geometry optimization algorithm;
generating, with the nozzle-geometry optimization algorithm, a first updated solid rocket motor nozzle design;
generating, with the temperature field algorithm, a second temperature field for the first updated solid rocket motor nozzle design using the at least one design parameter;
providing the second temperature field for the first updated solid rocket motor nozzle design to the nozzle-geometry optimization algorithm;
generating, with the nozzle-geometry optimization algorithm, a second updated solid rocket motor nozzle design; and
when the second updated solid rocket motor nozzle design meets a specified project requirement, creating a file for additively manufacturing the second updated solid rocket motor nozzle design.

13. The method as recited in claim 12, wherein the temperature field algorithm comprises a lattice-Boltzmann method.

14. The method as recited in claim 12, wherein generating the first temperature field for the initial solid rocket motor nozzle design further comprises:
generating multiple different temperature fields for the initial solid rocket motor nozzle design using different design parameters for each of the multiple different temperature fields; and
combining the multiple different temperature fields into a single first temperature field for the initial solid rocket motor nozzle design.

15. The method as recited in claim 14, wherein the different design parameters comprise boundary parameters based upon the at least one design parameter.

16. The method as recited in claim 12, wherein creating the file for additively manufacturing the second updated solid rocket motor nozzle design comprises creating commands to additively manufacture gyroid-pattern insulation.

17. The method as recited in claim 12, wherein creating the file for additively manufacturing the second updated solid rocket motor nozzle design comprises creating commands to additively manufacture active cooling channels within the second updated solid rocket motor nozzle design.

18. The method as recited in claim 12, wherein creating the file for additively manufacturing the second updated solid rocket motor nozzle design comprises creating commands to additively manufacture thermal energy management ducts within the second updated solid rocket motor nozzle design.

19. The method as recited in claim 12, wherein creating the file for additively manufacturing the second updated solid rocket motor nozzle design comprises creating commands to additively manufacture insulators such as composites, resins, plastics, or phenolic materials within the second updated solid rocket motor nozzle design.

20. The method as recited in claim 12, wherein:
generating the second updated solid rocket motor nozzle design comprises selecting one or more materials from a list of available materials to utilize when generating the second updated solid rocket motor nozzle design, wherein the one or more materials are selected based at least in part upon the second temperature field; and
creating commands within the file to additively manufacturing the second updated solid rocket motor nozzle design using the one or more materials.
